(19) United States
(12) Patent Application Publication
(10) Pub. No.: US 2024/0425354 A1
(43) Pub. Date: Dec. 26, 2024

(54) DEFORMATION MAPPING FOR OUT-OF-PLANE ACCELEROMETER OFFSET/SENSITIVITY SELF-CALIBRATION

(71) Applicant: InvenSense, Inc., San Jose, CA (US)

(72) Inventors: Roberto Martini, Milano (IT); Luca Coronato, Corsico (IT); Matthew Julian Thompson, Beaverton, OR (US)

(21) Appl. No.: 18/214,195

(22) Filed: Jun. 26, 2023

(51) Int. Cl. B81B 3/00; G01P 15/08; G01P 21/00

(52) U.S. Cl. CPC B81B 3/0027; G01P 15/08; G01P 21/00; B81B 2201/0235; B81B 2203/04; G01P 2015/0865

(57) ABSTRACT

A microelectromechanical system (MEMS) accelerometer incorporates deformation sensing with a plurality of sense electrodes positioned to facilitate determining a deformation pattern (e.g., asymmetric or symmetric) of an underlying substrate layer relative to a MEMS layer. The deformation pattern of the substrate layer contributes to offset and/or sensitivity of the accelerometer, so the determination of the deformation pattern enables processing circuitry to compensate and improve offset and/or sensitivity stability. Tilt sense electrodes and/or comparison electrodes may be incorporated alongside the plurality of sense electrodes to monitor deformation of the substrate layer relative to a fixed portion of the MEMS layer.

### CROSS-REFERENCE TO RELATED APPLICATION

This application incorporates by reference the entirety of the U.S. Patent Application entitled “MEMS Strain Sensitivity Calibration,” attorney Docket No. 000123-0108-101, filed concurrently herewith on the same day as the present application, which is incorporated by reference herein in its entirety.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognize skid or roll-over conditions).

MEMS sensors may be fabricated using semiconductor manufacturing techniques. A MEMS sensor may include movable proof masses that can respond to forces such as linear acceleration (e.g., for MEMS accelerometers), angular velocity (e.g., for MEMS gyroscopes), pressure, and magnetic field. The operation of these forces on the movable proof masses may be measured based on the movement of the proof masses in response to the forces. In some implementations, this movement is measured based on distance between the movable proof masses and fixed electrodes, which form capacitors for sensing the movement.

The MEMS sensor may include multiple layers that are manufactured to collectively form the sensor cavity and components, such as a MEMS layer, cap layer, and base substrate layer. These layers typically have parallel surfaces with respect to each other. The movable proof masses may be located in the MEMS layer. When fixed electrodes are also located within the MEMS layer, movement of the movable proof masses within the MEMS layer (e.g., in-plane movement) relative to the fixed electrodes may be used to measure a force along a plane of the MEMS layer. When fixed electrodes are located on another layer, movement of the movable proof masses outside the plane of the MEMS layer (e.g., out-of-plane movement) relative to the fixed electrodes may be used to measure a force out of the plane of the MEMS layer (e.g., perpendicular to the MEMS layer). The MEMS sensors may be designed based on expected relative locations of the movable proof masses and the fixed electrodes, both in the absence of external forces and in response to external forces. If a particular MEMS sensor departs from those expected relative locations due to factors such as manufacturing tolerances, wear, or external stresses applied to the sensor, the measurement of the desired force by the sensor may be inaccurate.

### SUMMARY

In an embodiment of the present disclosure, a MEMS sensor comprises a MEMS layer including a fixed portion and a proof mass, wherein the proof mass moves in response to an external excitation. The MEMS sensor further comprises a substrate layer, located beneath the MEMS layer, including a first plurality of sense electrodes associated with a first portion of the proof mass and a second plurality of sense electrodes associated with a second portion of the proof mass, wherein the first portion of the proof mass and the second portion of the proof mass each move normal to the MEMS layer, the first portion in a first direction and the second portion in a second direction opposite the first direction. The MEMS sensor further comprises processing circuitry configured to determine a deformation pattern of the substrate layer relative to the MEMS layer based on a comparison of signals received from the first plurality of sense electrodes and the second plurality of sense electrodes.

In an embodiment of the present disclosure, a method comprises receiving a first plurality of signals corresponding to a first plurality of sense electrodes positioned on an upper surface of a substrate layer, wherein each of the first plurality of signals is based on a first distance between a first portion of a proof mass and the first plurality of sense electrodes. The method further comprises receiving a second plurality of signals corresponding to a second plurality of sense electrodes positioned on the upper surface of the substrate layer, wherein each of the second plurality of signals is based on a second distance of a second portion of the proof mass from the second plurality of sense electrodes. The method further comprises multiplexing the first plurality of signals to create a first multiplexed signal, multiplexing the second plurality of signals to create a second multiplexed signal, and determining a deformation pattern of the substrate layer relative to a MEMS layer based on the first multiplexed signal and the second multiplexed signal.

In an embodiment of the present disclosure, a method comprises applying a first plurality of drive signals to a first plurality of sense electrodes positioned on an upper surface of a substrate layer, wherein each of the first plurality of sense electrodes generates a respective first signal based on a distance to a first portion of a proof mass in a MEMS layer to form a plurality of first signals. The method further comprises applying a second plurality of drive signals to a second plurality of sense electrodes positioned on the upper surface of the substrate layer, wherein each of the second plurality of sense electrodes generates a respective second signal based on a distance to a second portion of the proof mass in the MEMS layer to form a plurality of second signals. The method further comprises receiving a multiplexed signal from the proof mass, wherein the multiplexed signal includes the plurality of first signals and the plurality of second signals, and determining a deformation pattern of the substrate layer relative to the MEMS layer based on the multiplexed signal.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system in accordance with an embodiment of the present disclosure;

FIG. 2A shows an illustrative asymmetric deformation of a substrate layer causing an offset shift in accordance with an embodiment of the present disclosure;

FIG. 2B shows an illustrative symmetric deformation of a substrate layer causing a sensitivity shift in accordance with an embodiment of the present disclosure;

FIG. 3 shows a top view of out-of-plane sense electrode split sensing in accordance with an embodiment of the present disclosure;

FIG. 4 shows a top view of proof mass sensing in accordance with an embodiment of the present disclosure;

FIG. 5 shows a top view of out-of-plane sense electrode split sensing integrated with tilt sense electrodes in accordance with an embodiment of the present disclosure;

FIG. 6 shows a top view of out-of-plane sense electrode split sensing integrated with tilt sense electrodes and comparison electrodes in accordance with an embodiment of the present disclosure;

FIG. 7 shows an illustrative flowchart depicting system working modes in accordance with an embodiment of the present disclosure;

FIG. 8 shows an illustrative deformation mapping flowchart in accordance with an embodiment of the present disclosure;

FIG. 9 shows an illustrative flowchart for out-of-plane sense electrode split sensing in accordance with an embodiment of the present disclosure; and

FIG. 10 shows an illustrative flowchart for proof mass sensing in accordance with an embodiment of the present disclosure.

### DETAILED DESCRIPTION

There is a continuing desire to reduce MEMS device or sensor package thickness, for example, to make consumer products more cost effective or to fit the components in thinner devices and/or to allow other components (e.g., processing circuitry) to be fit on or proximate to a MEMS substrate. However, size reductions generally cause a degradation of offset and sensitivity stability for inertial sensors such as accelerometers. For example, out-of-plane accelerometers (e.g., sensitive to forces normal to a MEMS layer, or plane) may have a reduced transducer sensitivity, offer reduced offset and sensitivity stability, and may be constrained in their reduction of size by the presence of reference electrodes (e.g., to determine tilt of the MEMS layer), which require more area and increase the footprint of the out-of-plane accelerometer. Reference electrodes partially compensate for offset and sensitivity stability issues, but, in some embodiments, sense electrode deformation (e.g., caused by substrate layer deformation relative to the MEMS layer) dominates. It is desirable to improve offset and sensitivity stability and increase transducer sensitivity in out-of-plane accelerometers while minimizing their thickness and size.

Generally, example illustrations herein may employ multiple electrodes in place of single electrodes to enhance a degree to which deformation of a substrate beneath the multiple electrodes is understood and/or may be compensated for in a microelectromechanical system (MEMS) accelerometer. For example, in previous approaches a single electrode may have some amount of deformation in the substrate due to attrition, warping, damage, or the like, creating error in a sense signal associated with the electrode (e.g., in the form of an offset or sensitivity shift). By contrast, in the example approaches herein, a plurality of sense electrodes (e.g., with the electrodes relatively smaller individually, and positioned in different areas of the substrate corresponding to the proof mass) may be used to determine whether/how much deformation may have occurred in the substrate. The signals corresponding to each of the sense electrodes may be modulated together in any manner that is convenient. Additionally, example illustrations may apply these concepts to any electrode or capacitive sensing system that is convenient. Example approaches herein may be applied in the context of electrode(s) associated with a proof mass tilting or translating relative to the substrate, and/or to tilt sense electrodes associated with fixed components of a MEMS device.

Although the present disclosure may be described in the context of a MEMS accelerometer, it will be understood that the present disclosure also applies to other types of MEMS sensors that respond to external excitations, such as MEMS sensors that sense barometric pressure, Coriolis forces, sound pressure, magnetic forces and the like. As will be understood from the present disclosure, sense gaps at various locations can be evaluated to determine, map, and compensate for MEMS sensor operation.

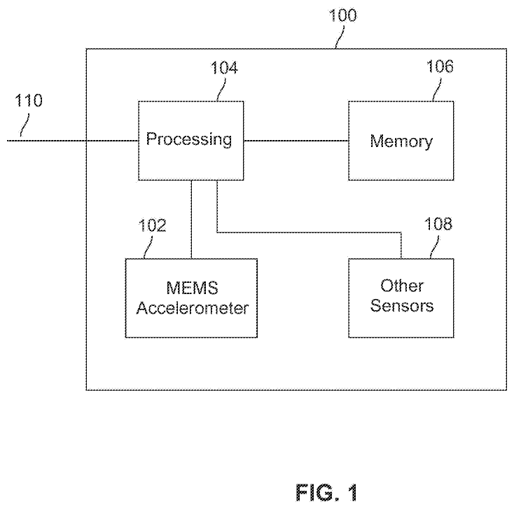

FIG. 1 shows an illustrative MEMS system 100 in accordance with an embodiment of the present disclosure. Although particular components are depicted in FIG. 1, it will be understood that other suitable combinations of the MEMS, processing components, memory, and other circuitry may be utilized as necessary for different applications and systems. In at least some embodiments, the circuitry, devices, systems, and methods described herein are described in the context of a system including processing circuitry configured to determine a deformation pattern of a substrate (e.g., CMOS) layer relative to a MEMS layer. More specifically, in at least some examples, the processing circuitry (e.g., processing circuitry 104) is configured to receive a first plurality of signals from a first plurality of sense electrodes, positioned on an upper surface, or plane, of the substrate layer, based on capacitive engagement with a first portion of a proof mass within the MEMS layer, in response to a linear acceleration, drive signal, etc. In addition, processing circuitry is configured to receive a second plurality of signals from a second plurality of sense electrodes, positioned on the upper surface of the substrate layer, based on capacitive engagement with a second portion of the proof mass within the MEMS layer, in response to the external excitation (e.g., linear acceleration), drive signal, etc. Processing circuitry (e.g., processing circuitry 104) respectively multiplexes the first plurality and the second plurality of signals (e.g., based on frequency, phase, amplitude, time, orthogonal codes, wavelength, etc.) and processes the signals to determine a deformation pattern of the substrate layer relative to the MEMS layer (e.g., based on the first and second multiplexed signal).

In some embodiments, processing circuitry (e.g., processing circuitry 104) is configured to apply a first plurality of drive signals to a first plurality of sense electrodes positioned on the upper surface, or plane, of the substrate layer. Based on a distance to the first portion of the proof mass within the MEMS layer, each of the first plurality of sense electrodes delivers a sense signal (e.g., a plurality of first signals) to the proof mass. Concurrently, processing circuitry applies a second plurality of drive signals to a second plurality of sense electrodes positioned on the upper surface of the substrate layer. Based on a distance to the second portion of the proof mass within the MEMS layer, each of the second plurality of sense electrodes delivers a sense signal (e.g., a plurality of second signals) to the proof mass. Processing circuitry (e.g., processing circuitry 104) is further configured to receive a modulated signal from the proof mass (e.g., including the plurality of first signals and the plurality of second signals) and determine the deformation pattern of the substrate (e.g., CMOS) layer relative to the MEMS layer based on the modulated signal. In some embodiments, processing circuitry may compensate an offset and/or sensitivity of an out-of-plane accelerometer (e.g., normal to the MEMS layer) based on the determination of the substrate layer deformation.

Processing circuitry 104 may include one or more components providing processing based on the requirements of the MEMS system 100. In some embodiments, processing circuitry 104 may include hardware control logic that may be integrated within a chip of a sensor (e.g., on a base substrate of a MEMS accelerometer 102 or other sensor 108, or on an adjacent portion of a chip to the MEMS accelerometer 102 or other sensor 108) to control the operation of the MEMS accelerometer 102 or other sensors 108 and perform aspects of processing for the MEMS accelerometer 102 or the other sensors 108. In some embodiments, the MEMS accelerometer 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the MEMS accelerometer 102 by interacting with the hardware control logic and processing signals received from MEMS accelerometer 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the MEMS accelerometer 102 or other sensors 108 may communicate directly with external circuitry (e.g., via a serial bus or direct connection to sensor outputs and control inputs), in an embodiment the processing circuitry 104 may process data received from the MEMS accelerometer 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the MEMS accelerometer 102 and other sensors 108 into appropriate measurement units (e.g., based on settings provided by other computing units communicating over the communication interface 110) and perform more complex processing to determine measurements such as orientation or Euler angles, and in some embodiments, to determine from sensor data whether a particular activity (e.g., walking, running, braking, skidding, rolling, etc.) is taking place. In some embodiments, some or all of the conversions or calculations may take place on the hardware control logic or other on-chip processing of the MEMS accelerometer 102 or other sensors 108.

In some embodiments, certain types of information may be determined based on data from multiple MEMS accelerometers 102 and other sensors 108 in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimensional cameras, industrial automation, and numerous other applications.

In accordance with the present disclosure, a MEMS accelerometer may include, in addition to the first plurality and the second plurality of sense electrodes, tilt sense electrodes positioned on the upper surface of the substrate (e.g., CMOS) layer. The tilt sense electrodes may be associated with a fixed portion of the MEMS layer (e.g., an anchor that connects the MEMS layer to the substrate layer) such that, in some embodiments, a distance between the fixed portion of the MEMS layer and the tilt sense electrodes may be used to determine a rigid rotation of the fixed portion of the MEMS layer and compensate for offset observed in an out-of-plane accelerometer. In some embodiments, the MEMS accelerometer may include, in addition to the first plurality of sense electrodes, the second plurality of sense electrodes, and the tilt sense electrodes, a first plurality and a second plurality of comparison electrodes positioned on the upper surface of the substrate layer. The first plurality of comparison electrodes may be located between a first tilt sense electrode and the first plurality of sense electrodes, and the second plurality of comparison electrodes may be located between a second tilt sense electrode and the second plurality of sense electrodes. In some embodiments, any layout of the first plurality and the second plurality of sense electrodes, the first and the second tilt sense electrodes, and the first plurality and the second plurality of comparison electrodes on the upper surface of the substrate (e.g., CMOS) layer may be used in the MEMS accelerometer described herein. The first plurality of comparison electrodes may be used to compare one or more signals to a tilt signal measured by the first tilt sense electrode, relative to the fixed portion of the MEMS layer, to estimate the tilt of the fixed portion of the MEMS layer, or, in some embodiments, the first plurality of comparison electrodes may be used to compare one or more signals to a first plurality of signals generated by the first plurality of sense electrodes, relative to the first portion of the proof mass, to estimate offset of the out-of-plane accelerometer. Similarly, the second plurality of comparison electrodes may be used to compare one or more signals to a tilt signal measured by the second tilt sense electrode, relative to the fixed portion of the MEMS layer, to estimate the tilt of the fixed portion of the MEMS layer, or, in some embodiments, the second plurality of comparison electrodes may be used to compare one or more signals to a second plurality of signals generated by the second plurality of sense electrodes, relative to the second portion of the proof mass, to estimate offset of the out-of-plane accelerometer.

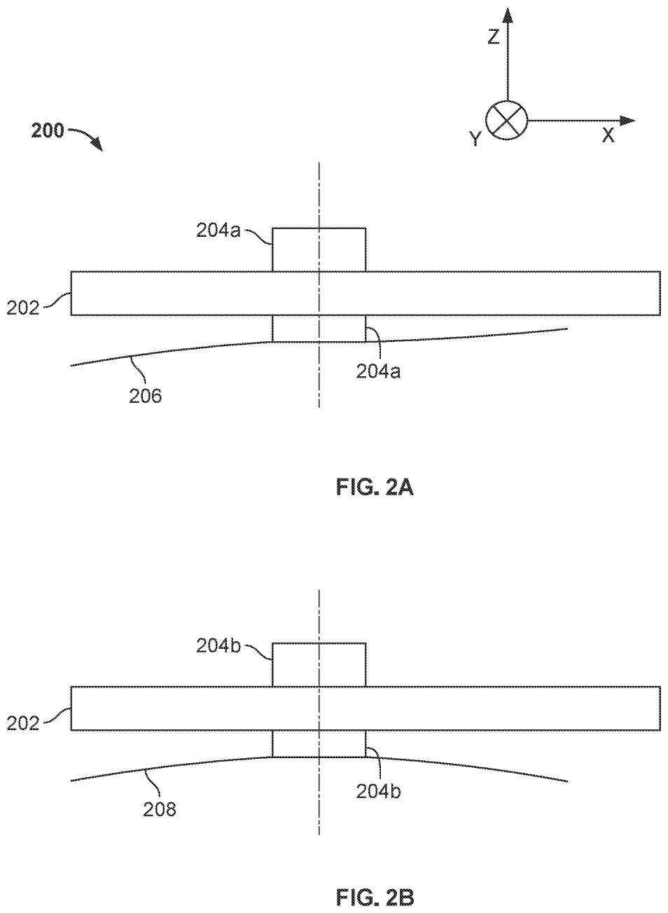

FIG. 2A shows an illustrative asymmetric deformation of a substrate layer causing an offset shift in accordance with an embodiment of the present disclosure, and FIG. 2B shows an illustrative symmetric deformation of a substrate layer causing a sensitivity shift in accordance with an embodiment of the present disclosure. In the depicted embodiments, system 200 includes MEMS layer 202, fixed portions 204a, 204b, asymmetrically deformed substrate layer 206, and symmetrically deformed substrate layer 208. In some embodiments, MEMS layer 202 may include movable components (e.g., a proof mass, in-plane springs, torsional springs, in-plane electrodes, etc.). In some embodiments, more than one fixed portion (e.g., an anchor that couples MEMS layer 202 to a substrate, or CMOS, layer) may be implemented in system 200. The more than one fixed portion may solely anchor in-plane components to out-of-plane components mechanically, or, in some embodiments, may also electrically couple (e.g., receive and/or deliver electrical signals) in-plane components to out-of-plane components. In some embodiments, asymmetrically deformed substrate layer 206 and/or symmetrically deformed substrate layer 208 may include out-of-plane components such as sense electrodes, tilt sense electrodes, comparison electrodes, processing circuitry, etc. Although particular components are depicted in certain configurations for system 200, components may be removed, modified, or substituted and additional components (e.g., electrodes, a proof mass, processing circuitry, etc.) may be added in certain embodiments.

FIG. 2A depicts an example of an asymmetrically deformed substrate layer 206 in response to, e.g., a package deformation. For example, a manufacturing error may cause a portion of substrate layer 206 to approach MEMS layer 202 (e.g., normal to the x-y plane), creating an asymmetric deformation, as depicted in system 200. Consequently, unintended capacitive engagement between out-of-plane sense electrodes, positioned on an upper surface of substrate layer 206, and a proof mass within MEMS layer 202 may create an offset during operation of the out-of-plane accelerometer. The asymmetrically deformed substrate layer 206 translates into out-of-plane offset that cannot be characterized and may contribute to inaccurate measurements performed by system 200. FIG. 2B depicts an example of a symmetrically deformed substrate layer 208 in response to, e.g., attrition of the MEMS device. For example, wear and tear of system 200 may chronically result in substrate layer 208 symmetrically moving away from MEMS layer 202 (e.g., normal to the x-y plane), creating a symmetric deformation as depicted in FIG. 2B. Accordingly, system 200 may be less sensitive to linear acceleration normal to the MEMS layer or plane (e.g., out of the illustrated x-y plane in the negative z direction). Thus, symmetrically deformed substrate layer 208 may contribute to inaccurate measurements by system 200.

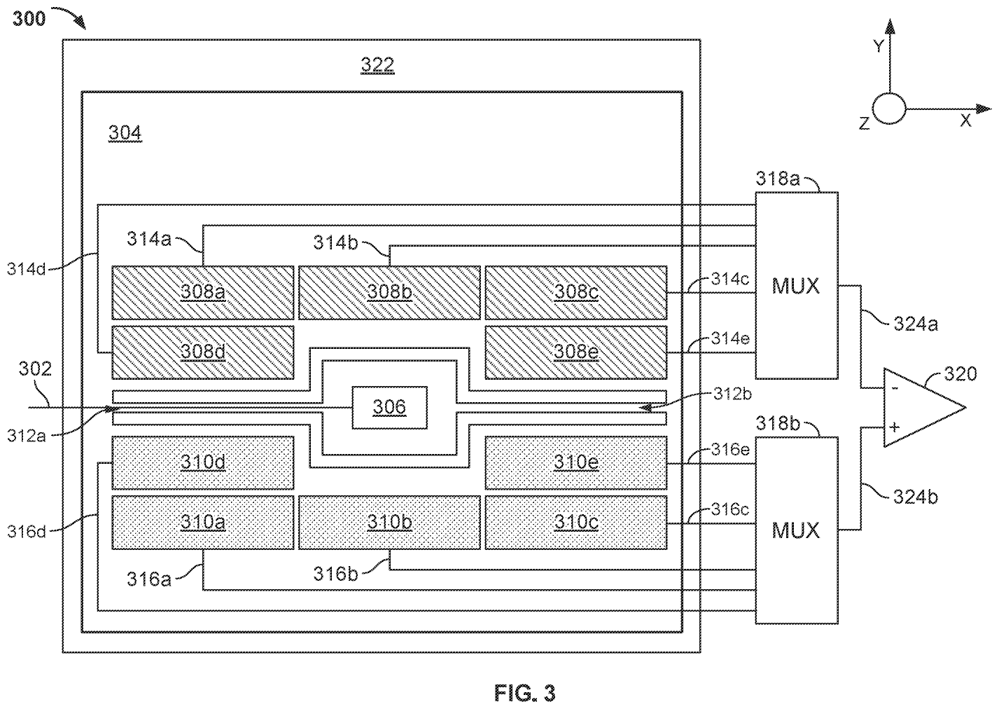

FIG. 3 shows a top view of out-of-plane sense electrode split sensing in accordance with an embodiment of the present disclosure, which may be employed to address the offset and sensitivity problems that might otherwise result from the wear and/or deformation discussed above. In the depicted embodiment, system 300 includes drive signal 302, proof mass 304, fixed portion 306, a first plurality of sense electrodes 308a-308e, a second plurality of sense electrodes 310a-310e, torsional springs 312a, 312b, a first plurality of signals 314a-314e, a second plurality of signals 316a-316e, multiplexers (MUXs) 318a, 318b, capacitance-to-voltage (C2V) converter 320, substrate (e.g., CMOS) layer 322, first multiplexed signal 324a, and second multiplexed signal 324b. In some embodiments, a MEMS layer, which includes proof mass 304, torsional springs 312a, 312b, and fixed portion 306 (e.g., an anchor that couples the MEMS layer to the substrate layer 322), may also include movable in-plane components (e.g., in-plane sense electrodes, in-plane springs, etc.). In some embodiments, one or more anchors may connect the MEMS layer to the substrate layer 322 such that, e.g., the one or more anchors mechanically couple in-plane components to out-of-plane components, or the one or more anchors electrically couple (e.g., to receive and/or deliver signals) in-plane components to out-of-plane components. In some embodiments, any number of torsional springs may connect proof mass 304 to fixed portions of the MEMS layer. Although particular components are depicted in certain configurations for system 300, components may be removed, modified, or substituted and additional components (e.g., electrodes, springs, anchors, processing circuitry, etc.) may be added in certain embodiments.

In example illustrations, multiple sense electrodes may generally be employed to compensate for positional differences between the sense electrodes with respect to proof mass 304, for example, that may result from symmetric or asymmetric deformation in substrate layer 322 underlying the sense electrodes. The first plurality of sense electrodes 308a-308e is positioned on an upper surface, or plane, of substrate layer 322 beneath a first portion of proof mass 304 within the MEMS layer, and the second plurality of sense electrodes 310a-310e, split from the first plurality of sense electrodes 308a-308e, is positioned on the upper surface of substrate layer 322 beneath a second portion of proof mass 304 within the MEMS layer. Fixed portion 306 (e.g., an anchor) connects the MEMS layer to the substrate layer 322 and stabilizes movable components (both in-plane and out-of-plane) within the MEMS layer (e.g., within the x-y plane) to the substrate layer 322. In some embodiments, any number of sense electrodes may be incorporated into system 300 to detect a deformation pattern of substrate layer 322 with respect to the MEMS layer (e.g., including proof mass 304). It will be understood that the first plurality of sense electrodes 308a-308e and the second plurality of sense electrodes 310a-310e may respectively have a uniform surface area, or, in some embodiments, may have different surface areas. The first plurality of sense electrodes 308a-308e are of a first polarity (e.g., a positive charge), and the second plurality of sense electrodes 310a-310e are of a second polarity opposite from the first polarity (e.g., a negative charge). Proof mass 304 is suspended in the MEMS layer, via torsional springs 312a, 312b, such that the proof mass 304 rotates about the torsional springs 312a, 312b in response to a force of interest such as a z-axis linear acceleration. Accordingly, a first portion of proof mass 304 may move out-of-plane (e.g., rotate out of the x-y plane) with respect to the first plurality of sense electrodes 308a-308e (e.g., forming a first moving capacitor) and a second portion of proof mass 304 may move out-of-plane in the opposite direction (e.g., rotate out of the x-y plane) with respect to the second plurality of sense electrodes 310a-310e (e.g., forming a second moving capacitor) in response to a linear acceleration along the z-axis. In some embodiments, processing circuitry (e.g., processing circuitry 104 including a phase-locked loop (PLL)) may deliver drive signal 302 (e.g., a square signal) that modulates signal changes corresponding to movements of the proof mass caused by linear acceleration.

Although not depicted in FIG. 3, In some embodiments, proof mass 304 may translate in-plane (e.g., within the MEMS layer and the x-y plane), in response to an in-plane linear acceleration with respect to in-plane MEMS components (e.g., in-plane sense electrodes, in-plane springs, fixed portion 306, etc.). It will be understood that the first portion of proof mass 304 moves, with respect to the first plurality of sense electrodes 308a-308e, in a first direction, and the second portion of proof mass 304 moves, with respect to the second plurality of sense electrodes 310a-310e, in a second direction opposite the first direction. In some embodiments, torsional springs 312a, 312b may be rigid in a direction within the MEMS layer (e.g., in the x-y plane) to ensure proof mass 304 accurately measures out-of-plane acceleration. In some embodiments, the MEMS layer may include in-plane springs coupled to proof mass 304 that are rigid in directions other than a movement to be measured within the x-y plane to ensure proof mass 304 accurately measures in-plane acceleration. In response to, e.g., an out-of-plane linear acceleration (e.g., normal to the MEMS layer in the x-y plane) the first portion of proof mass 304 may move either closer to or farther away from (e.g., capacitively engage with) the first plurality of sense electrodes 308a-308e with a degree of rotation based on the magnitude of the out-of-plane acceleration or drive signal 302.

Movement of the proof mass 304 may be sensed by the first plurality of sense electrodes 308a-308e and used to determine a force or acceleration applied to the device 300. For example, a linear acceleration causes a movement of the first portion of proof mass 304 with respect to the first plurality of sense electrodes 308a-308e may generate the first plurality of signals 314a-314e (e.g., a first plurality of capacitive signals), commensurate to the out-of-plane acceleration or drive signal 302, that is outputted to MUX 318a by the first plurality of sense electrodes 308a-308e. Similarly, the second portion of proof mass 304 may move either closer to or farther away from (e.g., capacitively engage with) the second plurality of sense electrodes 310a-310e with a degree of rotation based on the magnitude of the out-of-plane acceleration or drive signal 302. The linear acceleration also causes a corresponding and opposite-direction movement of the second portion of proof mass 304 with respect to the second plurality of sense electrodes 310a-310e generates the second plurality of signals 316a-316e (e.g., a second plurality of capacitive signals), commensurate to the out-of-plane acceleration, that is outputted to MUX 318b by the second plurality of sense electrodes 310a-310e.

MUX 318a receives the first plurality of signals 314a-314e from the first plurality of sense electrodes 308a-308e and forwards a first multiplexed signal 324a to C2V converter 320, and MUX 318b receives the second plurality of signals 316a-316e from the second plurality of sense electrodes 310a-310e and forwards a second multiplexed signal 324b to C2V converter 320. In some embodiments, MUXs 318a, 318b may respectively multiplex the first plurality of signals 314a-314e and the second plurality of signals 316a-316e with respect to frequency, time, wavelength, phase, amplitude, or orthogonal codes. C2V converter 320 receives the first multiplexed signal 324a, receives the second multiplexed signal 324b, and outputs a signal that includes information about a deformation of the substrate layer 322 with respect to the MEMS layer, e.g., based on which signals of signals 314a-314e are compared with which signals of 316a-316e. For example, by comparison of different respective ones of signals associated with different electrodes, different deformation patterns across different locations (e.g., 308c with respect to 310c, 308c with respect to 310a, etc.) may be utilized to perform a complex and detailed mapping of relative deformations at different regions of the substrate 322.

In at least some examples, a deformation pattern (e.g., an asymmetric or symmetric pattern) of the substrate layer 322 with respect to the MEMS layer is determined based on analyzing the output over time (e.g., including comparison of multiple respective locations with respect to each other) of the comparison by C2V converter of first multiplexed signal 324a and the second multiplexed signal 324b, which enables processing circuitry (e.g., processing circuitry 104) to improve offset and/or sensitivity stability of the out-of-plane accelerometer and more accurately estimate out-of-plane acceleration. In some embodiments, out-of-plane accelerometer sensitivity may be corrected by measuring a common mode gap of the respective first plurality of sense electrodes 308a-308e and second plurality of sense electrodes 310a-310e at the same distance from the rotation axis and multiplying the common mode gap by each electrode position of the first and second plurality of sense electrodes. In some embodiments, out-of-plane accelerometer offset may be compensated by checking the drift of each of the first plurality of signals 314a-314e and the second plurality of signals 316a-316e. It will be understood that the respective sensing nodes 308a-308e and 310a-310e may either be connected to a single C2V converter for both an operation mode and a self-calibration mode or connected to individual C2V converters for operation mode and self-calibration mode.

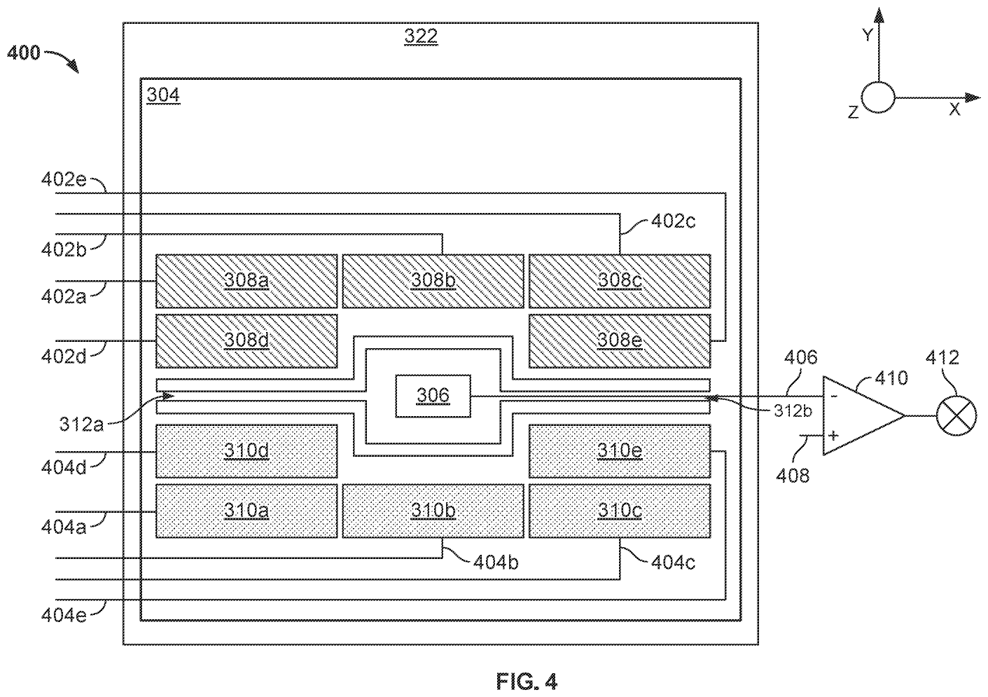

FIG. 4 shows a top view of proof mass sensing in accordance with an embodiment of the present disclosure. In the depicted embodiment, system 400 includes proof mass 304, fixed portion 306, the first plurality of sense electrodes 308a-308e, the second plurality of sense electrodes 310a-310e, torsional springs 312a, 312b, and substrate (e.g., CMOS) layer 322 of FIG. 3. In addition, system 400 includes a first plurality of drive signals 402a-402e, a second plurality of drive signals 404a-404e, a modulated signal 406, a reference signal 408 (e.g., in a half-bridge configuration), a capacitance-to-voltage (C2V) converter 410, and a demodulator 412. In an embodiment of a full-bridge configuration, the reference signal may be provided from an output of another accelerometer. Although particular components are depicted in certain configurations for system 400, components may be removed, modified, or substituted and additional components (e.g., electrodes, springs, anchors, processing circuitry, etc.) may be added in certain embodiments.

Processing circuitry (e.g., a PLL of processing circuitry 104) respectively delivers the first plurality of drive signals 402a-402e to the first plurality of sense electrodes 308a-308e and the second plurality of drive signals 404a-404e to the second plurality of sense electrodes 310a-310e. Each of the first plurality of drive signals 402a-402e provides a modulating signal for each of the first plurality of sense electrodes 308a-308e to capacitively engage with the first portion of proof mass 304, which, based on a differential of the out-of-plane movement of the first portion of proof mass 304 (e.g., normal to the MEMS layer within the x-y plane) with respect to the first plurality of sense electrodes 308a-308e, generates a first plurality of capacitive signals at proof mass 304. Similarly, each of the second plurality of drive signals 404a-404e provides a modulating signal for each of the second plurality of sense electrodes 310a-310e to capacitively engage with the second portion of proof mass 304, which, based the out-of-plane movement of the second portion of proof mass 304 (e.g., normal to the MEMS layer within the x-y plane) with respect to the second plurality of sense electrodes 310a-310e, results in a second plurality of capacitive signals at proof mass 304. It will be understood that proof mass 304 is suspended in the MEMS layer, via torsional springs 312a, 312b, such that the proof mass 304 rotates about the torsional springs 312a, 312b with respect to the first plurality and the second plurality of sense electrodes. The proof mass 304 effectively multiplexes the first plurality of capacitive signals, received from the first plurality of sense electrodes 308a-308e, and the second plurality of capacitive signals, received from the second plurality of sense electrodes 310a-310e, and modulates the signal based on the movement of the proof mass, to create multiplexed signal 406. In some embodiments, the signals at the proof mass 304 may be multiplexed with respect to each other based on frequency, phase, amplitude, time, wavelength, orthogonal codes, or suitable combinations thereof.

Proof mass 304 delivers multiplexed signal 406 to processing circuitry C2V converter 410, which provides an output signal to demultiplexer 412. Demultiplexer 412 separates the multiplexed signal 406, e.g., based on frequency, time, phase, amplitude, wavelength, orthogonal codes, etc. and delivers the corresponding capacitive signals to the processing circuitry for analysis, for example, to determine the deformation pattern (e.g., an asymmetric or symmetric pattern) of the substrate layer 322 with respect to the MEMS layer, by mapping sense gaps in different locations of the proof mass 304 (e.g., based on signals provided from particular positions of the first and second plurality of sense electrodes). The determination of the substrate layer 322 deformation enables system 400 to improve offset and/or sensitivity stability of the out-of-plane accelerometer and more accurately estimate out-of-plane acceleration.

In an embodiment, signal 408 is provided from a second proof mass system including a similar configuration of a proof mass system and sense electrodes. In some embodiments, the second system may be designed identically to the first proof mass system, in a manner such that similar signals should respond in a similar manner at similar times in the absence of a deformation of the substrate. This may provide information about a second portion of the substrate as well as additional differential sensing resolution.

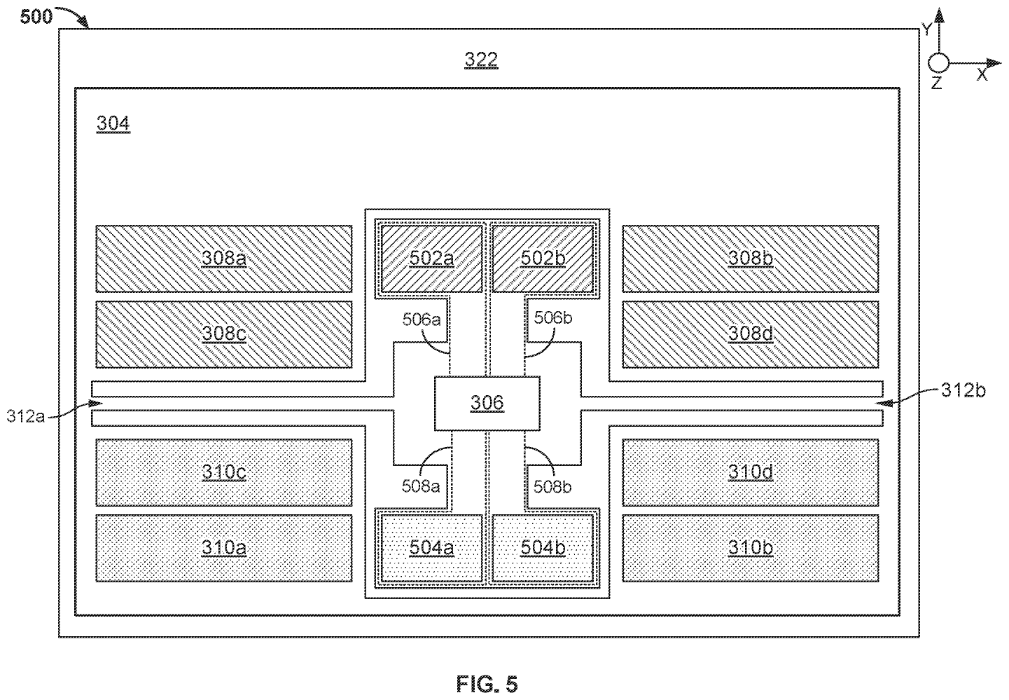

FIG. 5 shows a top view of out-of-plane sense electrode split sensing integrated with tilt sense electrodes in accordance with an embodiment of the present disclosure. Although FIG. 5 may be described in a particular manner, it will be understood that signals of FIG. 5 may be applied and processed in a suitable manner to facilitate split sensing (e.g., via sense electrodes) or multiplexed proof mass sensing, as described herein. In the depicted embodiment, system 500 includes proof mass 304, fixed portion 306, the first plurality of sense electrodes 308a-308d, the second plurality of sense electrodes 310a-310d, torsional springs 312a, 312b, and substrate (e.g., CMOS) layer 322 of FIG. 3. In addition, system 500 includes a first plurality of tilt sense (e.g., reference) electrodes 502a, 502b, a second plurality of tilt sense (e.g., reference) electrodes 504a, 504b, a first plurality of paddles 506a, 506b of the fixed portion 306, and a second plurality of paddles 508a, 508b of the fixed portion 306. It will be understood that proof mass 304 is suspended in the MEMS layer, via torsional springs 312a, 312b, such that proof mass 304 rotates about the torsional springs 312a, 312b with respect to the first plurality and the second plurality of sense electrodes. Although particular components are depicted in certain configurations for system 500, components may be removed, modified, or substituted and additional components (e.g., electrodes, springs, anchors, processing circuitry, etc.) may be added in certain embodiments.

The first plurality of tilt sense electrodes 502a, 502b is positioned on the upper surface, or plane, of the substrate layer 322 beneath a first plurality of paddles 506a, 506b of the fixed portion 306 on a lower surface of the MEMS layer, and the second plurality of tilt sense electrodes 504a, 504b, split from the first plurality of tilt sense electrodes 502a, 502b, is positioned on the upper surface of the substrate layer 322 beneath a second plurality of paddles 508a, 508b of the fixed portion 306 on the lower surface of the MEMS layer. Generally, the first plurality of paddles 506a, 506b and the second plurality of paddles 508a, 508b of the fixed portion 306 extend parallel to the substrate layer 322 and enable system 500 to determine whether/how much the MEMS layer (e.g., including proof mass 304 and fixed portion 306) has rotated, or tilted, with respect to the substrate layer 322. In some embodiments, any number of tilt sense electrodes may be implemented into system 500 to compensate for offset observed in the out-of-plane accelerometer. In some embodiments, the first plurality of tilt sense electrodes 502a, 502b and the second plurality of tilt sense electrodes 504a, 504b may respectively have a uniform surface area, or, in some embodiments, may have different surface areas. The first plurality of tilt sense electrodes 502a, 502b are of a first polarity (e.g., a positive charge), and the second plurality of tilt sense electrodes 504a, 504b are of a second polarity opposite the first polarity (e.g., a negative charge). A change in distance between the first plurality of paddles 506a, 506b of the fixed portion 306 and the first plurality of tilt sense electrodes 502a, 502b results in a change in capacitance that corresponds to a rigid rotation, or tilt, (e.g., out of the x-y plane) of the first plurality of paddles 506a, 506b of the fixed portion 306 in a first direction. A change in distance between the second plurality of paddles 508a, 508b of the fixed portion 306 and the second plurality of tilt sense electrodes 504a, 504b results in a change in capacitance that corresponds to a rigid rotation, or tilt, (e.g., out of the x-y plane) of the second plurality of paddles 508a, 508b of the fixed portion 306 in a second direction opposite the first direction, which translates into a second plurality of tilt sense signals.

In some embodiments, each of the first plurality of tilt sense electrodes 502a, 502b delivers a tilt sense signal to processing circuitry (e.g., including a first MUX) to generate a first multiplexed tilt sense signal, and each of the second plurality of tilt sense electrodes 504a, 504b delivers a tilt sense signal to processing circuitry (e.g., including a second MUX) to generate a second multiplexed tilt sense signal such that the first plurality and the second plurality of tilt sense signals are read sequentially. The first and the second multiplexed tilt sense signals may be used to compensate offset of the out-of-plane accelerometer and more accurately estimate out-of-plane acceleration. In some embodiments, processing circuitry may apply a first plurality of drive signals to the first plurality of tilt sense electrodes 502a, 502b and a second plurality of drive signals to the second plurality of tilt sense electrodes 504a, 504b. Each of the first plurality of drive signals modulates a sensed signal between the first plurality of tilt sense electrodes 502a, 502b and the first plurality of paddles 506a, 506b of the fixed portion 306, which, based on a distance to the first plurality of paddles 506a, 506b of the fixed portion 306, generates a first plurality of tilt sense signals that are delivered to proof mass 304 via fixed portion 306. Similarly, each of the second plurality of drive signals modulates a sensed signal between the second plurality of tilt sense electrodes 504a, 504b and the second plurality of paddles 508a, 508b of the fixed portion 306, which, based on a distance to the second plurality of paddles 508a, 508b of the fixed portion 306, generates a second plurality of tilt sense signals that are delivered to proof mass 304 via fixed portion 306. The proof mass 304 modulates the first plurality of tilt sense signals, received from the first plurality of tilt sense electrodes 502a, 502b, and the second plurality of tilt sense signals, received from the second plurality of tilt sense electrodes 504a, 504b, based on the tilt to create a modulated tilt sense signal. The resulting signal or signals are delivered via components such as a C2V converter and demultiplexer as described herein to processing circuitry, which determines the contribution of MEMS layer tilt to the offset observed in the out-of-plane accelerometer and compensates accordingly. In some embodiments, the first and the second plurality of tilt sense signals may be used to evaluate when to run a self-calibration of system 500. For example, if a reading from the first plurality of tilt sense electrodes 502a, 502b, with respect to the first plurality of paddles 506a, 506b of the fixed portion 306, and/or the second plurality of tilt sense electrodes 504a, 504b, with respect to the second plurality of paddles 508a, 508b of the fixed portion 306, exceeds a threshold displacement value, processing circuitry (e.g., processing circuitry 104) may calibrate system 500 to determine how much MEMS layer tilt contributes to out-of-plane accelerometer offset.

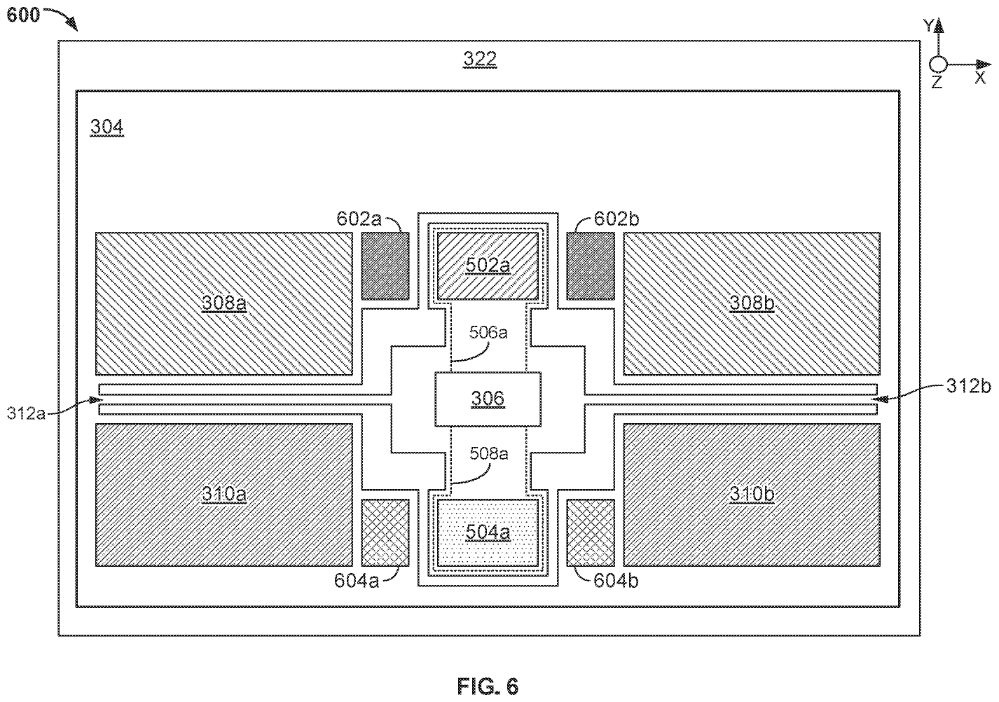

FIG. 6 shows a top view of out-of-plane sense electrode split sensing integrated with tilt sense electrodes and comparison electrodes in accordance with an embodiment of the present disclosure. Although FIG. 6 may be described in a particular manner, it will be understood that signals of FIG. 6 may be applied and processed in a suitable manner to facilitate split sensing (e.g., via sense electrodes) or multiplexed proof mass sensing, as described herein. In the depicted embodiment, system 600 includes proof mass 304, fixed portion 306, the first plurality of sense electrodes 308a, 308b, the second plurality of sense electrodes 310a, 310b, torsional springs 312a, 312b, and substrate (e.g., CMOS) layer 322 of FIG. 3. In addition, system 600 includes first tilt sense (e.g., reference) electrode 502a, first paddle 506a of the fixed portion 306, second tilt sense (e.g., reference) electrode 504a, and second paddle 508a of the fixed portion 306 of FIG. 5 as well as a first plurality of comparison electrodes 602a, 602b and a second plurality of comparison electrodes 604a, 604b. Although particular components are depicted in certain configurations for system 600, components may be removed, modified, or substituted and additional components (e.g., electrodes, springs, anchors, processing circuitry, etc.) may be added in certain embodiments.

The first plurality of comparison electrodes 602a, 602b is positioned on the upper surface, or plane, of the substrate layer 322 between the first tilt sense electrode 502a and the first plurality of sense electrodes 308a, 308b, and the second plurality of comparison electrodes 604a, 604b is positioned on the upper surface of the substrate layer 322 between the second tilt sense electrode 504a and the second plurality of sense electrodes 310a, 310b. Further, the first plurality of comparison electrodes 602a, 602b is positioned beneath the first portion of proof mass 304 within the MEMS layer, and the second plurality of comparison electrodes 604a, 604b, split from the first plurality of comparison electrodes 602a, 602b, is positioned beneath the second portion of proof mass 304 within the MEMS layer. In some embodiments, any number of comparison electrodes may be incorporated into system 600. In some embodiments, the first plurality of comparison electrodes 602a, 602b and the second plurality of comparison electrodes 604a, 604b may respectively have a uniform surface area, or, in some embodiments, may have different surface areas. As illustrated in FIG. 6, in some example approaches each of the comparison electrodes 602a, 602b, 604a, and 604b may have a smaller surface area than the sense electrodes 308a, 308b, 310a, and 310b present in system 600. A smaller surface area of the comparison electrodes 602a, 602b, 604a, and/or 604b may generally enhance characterization of the substrate layer 322 deformation and optimize the accuracy of the out-of-plane accelerometer. Further, as also shown in FIG. 6, in some embodiments the comparison electrodes may each have a smaller surface area than either the tilt sense electrodes 502a, 504a or the sense electrodes 308a, 308b, 310a, and 310b. The first plurality of comparison electrodes 602a, 602b are of a first polarity (e.g., a positive charge), and the second plurality of comparison electrodes 604a, 604b are of a second polarity opposite from the first polarity (e.g., a negative charge). In response to, e.g., a drive signal, an out-of-plane linear acceleration, etc., the first portion of proof mass 304 may move out-of-plane (e.g., out of the x-y plane), with respect to the first plurality of comparison electrodes 602a, 602b, in a first direction (e.g., either towards or away from the first plurality of comparison electrodes 602a, 602b), and the second portion of proof mass 304 may move out-of-plane (e.g., out of the x-y plane), with respect to the second plurality of comparison electrodes 604a, 604b, in a second direction (e.g., either towards or away from the second plurality of comparison electrodes 604a, 604b) opposite the first direction. Accordingly, a first moving capacitor is formed between the first portion of proof mass 304 and the first plurality of comparison electrodes 602a, 602b, and a second moving capacitor is formed between the second portion of proof mass 304 and the second plurality of comparison electrodes 604a, 604b. Proof mass 304 is suspended in the MEMS layer, via torsional springs 312a, 312b, such that the proof mass 304 rotates about the torsional springs 312a, 312b with respect to the first plurality and the second plurality of comparison electrodes as well as the first plurality and the second plurality of sense electrodes. The resulting capacitors of the first portion of proof mass 304 with respect to the first plurality of comparison electrodes 602a, 602b generates a first plurality of comparison signals, commensurate out-of-plane acceleration and modulated and multiplexed based on a provided drive signal, that is outputted to processing circuitry (e.g., including a first MUX) to generate a first multiplexed comparison signal. The resulting capacitors of the second portion of proof mass 304 with respect to the second plurality of comparison electrodes 604a, 604b generates a second plurality of comparison signals, commensurate out-of-plane acceleration and modulated and multiplexed based on provided drive signals, that is outputted to processing circuitry (e.g., including a second MUX) to generate a second multiplexed comparison signal.

In some embodiments, the first and the second multiplexed comparison signals may be compared with one or more multiplexed tilt sense signals originating from the first tilt sense electrode 502a and/or the second tilt sense electrode 504a, which estimate MEMS layer tilt via a distance to the first and/or the second paddle (e.g., the first paddle 506a and/or the second paddle 508a) of the fixed portion 306. In some embodiments, the first and the second multiplexed comparison signals may estimate one or more multiplexed signals originating from the first plurality of sense electrodes 308a, 308b and/or the second plurality of sense electrodes 310a, 310b (e.g., in the case of pure rotation of the proof mass 304), and, in some embodiments, the first and the second multiplexed comparison signals may be compared with one or more multiplexed signals originating from the first plurality of sense electrodes 308a, 308b and/or the second plurality of sense electrodes 310a, 310b to estimate out-of-plane accelerometer offset due to deformation (e.g., asymmetric or symmetric) of the substrate layer 322. In some embodiments, processing circuitry may apply a first plurality of drive signals to the first plurality of comparison electrodes 602a, 602b and a second plurality of drive signals to the second plurality of comparison electrodes 604a, 604b. Each of the first plurality of drive signals modulates a signal provided at each of the first plurality of comparison electrodes 602a, 602b to effectively multiplex capacitive signals formed with first portion of proof mass 304, which, based on the out-of-plane movement of the first portion of proof mass 304 (e.g., normal to the MEMS layer within the x-y plane) with respect to the first plurality of comparison electrodes 602a, 602b, generates a first plurality of comparison signals that are sensed at proof mass 304. Similarly, each of the second plurality of drive signals modulates a signal provided at each of the second plurality of comparison electrodes 604a, 604b to effectively multiplex capacitive signals formed with the second portion of proof mass 304, which, based the out-of-plane movement of the second portion of proof mass 304 (e.g., normal to the MEMS layer within the x-y plane) with respect to the second plurality of comparison electrodes 604a, 604b, generates a second plurality of comparison signals that are sensed at proof mass 304 6. The proof mass 304 modulates and effectively multiplexes the first plurality of comparison signals, received from the first plurality of comparison electrodes 602a, 602b, and the second plurality of comparison signals, received from the second plurality of comparison electrodes 604a, 604b, to create a multiplexed comparison signal. Proof mass 304 delivers the multiplexed comparison signal to processing circuitry (e.g., via a C2V converter and a demultiplexer), which, in some embodiments, compares the modulated comparison signal with a modulated tilt sense signal, originating from the first tilt sense electrode 502a and the second tilt sense electrode 504a, to estimate MEMS layer tilt. In some embodiments, the modulated comparison signal may estimate a modulated signal originating from the first plurality of sense electrodes 308a, 308b and/or the second plurality of sense electrodes 310a, 310b (e.g., in the case of pure rotation of the proof mass 304), and, in some embodiments, the modulated comparison signal may be compared with a modulated signal originating from the first plurality of sense electrodes 308a, 308b and/or the second plurality of sense electrodes 310a, 310b to estimate out-of-plane accelerometer offset due to deformation (e.g., asymmetric or symmetric) of the substrate layer 322. In some embodiments, the first plurality of comparison electrodes 602a, 602b and the second plurality of comparison electrodes 604a, 604b may be utilized within system 600 as self-test electrodes.

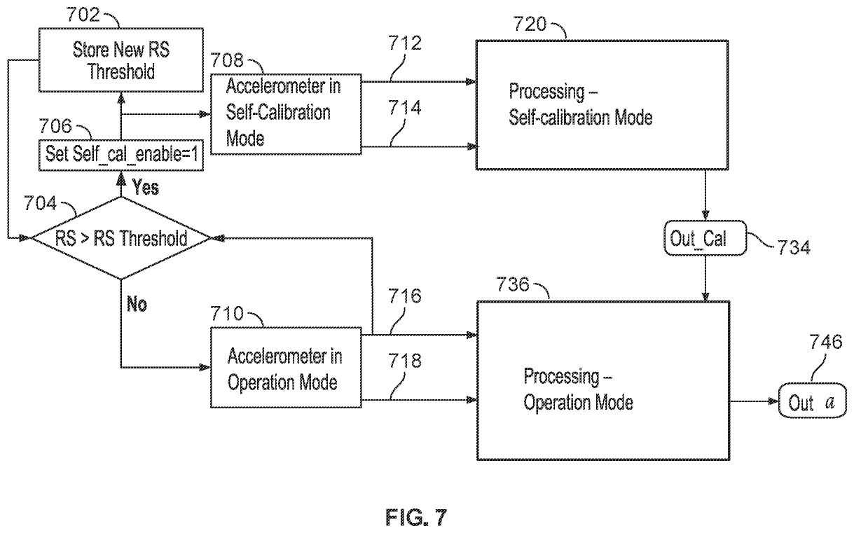

FIG. 7 shows an illustrative flowchart depicting system working modes in accordance with an embodiment of the present disclosure. Although particular steps are depicted in certain configurations for FIG. 7, steps may be removed, modified, or substituted and additional steps may be added in certain embodiments. At step 702, processing circuitry (e.g., processing circuitry 104) stores a new tilt sense (RS) threshold (e.g., a threshold distance between the first paddle 506a of the fixed portion 306 and the first tilt sense electrode 502a and between the second paddle 508a of the fixed portion 306 and the second tilt sense electrode 504a). In some embodiments, processing circuitry (e.g., processing circuitry 104) may store the new RS threshold in memory (e.g., memory 106). Step 702 may be useful in embodiments where tilt sense electrodes are present (e.g., for use in systems illustrated in FIGS. 5 and 6), however, in some embodiments, step 702 may be removed if tilt sense electrodes are not present (e.g., in FIGS. 3 and 4).

Step 704 is a decision block where, depending on the determination by processing circuitry (e.g., processing circuitry 104) of whether a measured deformation associated with the tilt sense (RS) electrodes (e.g., first tilt sense electrode 502a and second tilt sense electrode 504a) and the fixed portion of the MEMS layer (e.g., fixed portion 306) exceeds a threshold value, the flowchart either proceeds to operation mode or self-calibration mode (e.g., the working modes). In some embodiments, processing circuitry determines RS<RS Threshold (e.g., the distance between the first paddle 506a of the fixed portion 306 and the first tilt sense electrode 502a or between the second paddle 508a of the fixed portion 306 and the second tilt sense electrode 504a is less than the threshold distance), in which case processing circuitry (e.g., processing circuitry 104) advances to step 710 and enters operation mode (e.g., a self_cal_enable code is set to zero).

In the operation mode 710 Sense (AS) electrodes (e.g., the first plurality of sense electrodes 308a, 308b and the second plurality of sense electrodes 310a, 310b) are coupled with comparison (ARS) electrodes (e.g., the first plurality of comparison electrodes 602a, 602b and the second plurality of comparison electrodes 604a, 604b) to jointly output an out-of-plane acceleration signal relative to, e.g., the first and second portions of proof mass 304, to processing operation mode 736 via signal path 718. Operation mode 710 also includes tilt sense (RS) electrodes (e.g., the first tilt sense electrode 502a and the second tilt sense electrode 504a), which output a tilt signal relative to, e.g., the fixed portion 306 of the MEMS layer to processing operation mode 736 via signal path 716.

Processing operation mode 736 receives the tilt signal (e.g., RS) via signal path 716 the out-of-plane acceleration signal (e.g., AS+ARS) via signal path 718, and processes the output to generate an output acceleration signal 746, in accordance with the following:

$$a = {G}_{AS} [ Δ {C}_{AS} ( a ) + Δ {C}_{ARS} ( a ) ] - {G}_{RS} Δ {C}_{RS} \qquad ( 1 )$$

where:
G_{AS}=Gain of sense (AS) electrode signal path in operation mode
ΔC_{AS}=Differential of capacitive engagement between sense (AS) electrodes and proof mass
ΔC_{ARS}=Differential of capacitive engagement between comparison (ARS) electrodes and proof mass
G_{RS}=Gain of tilt sense (RS) electrode signal path in operation mode
ΔC_{RS}=Differential of capacitive engagement between tilt sense (RS) electrodes and fixed portion of the MEMS layer

In some embodiments, out-of-plane accelerometer offset due to substrate deformation (e.g., O_{selfcal}) is computed by processing circuitry in self-calibration mode 720 and stored, based on comparison electrode signals (ARS) received via signal path 712 and sense electrode signals (AS) received via sense path 714. The computed value will be then used when device goes back to operation mode via output block 734.

Returning to decision block 704, in some embodiments, processing circuitry (e.g., processing circuitry 104) determines RS>RS Threshold (e.g., the distance between the first paddle 506a of the fixed portion 306 and the first tilt sense electrode 502a or between the second paddle 508a of the fixed portion 306 and the second tilt sense electrode 504a exceeds the threshold distance), in which case processing circuitry advances to step 706 where the self_cal_enable code is set to one and processing circuitry enters self-calibration mode at step 708. Sense (AS) electrodes (e.g., the first plurality of sense electrodes 308a, 308b and the second plurality of sense electrodes 310a, 310b) and comparison (ARS) electrodes (e.g., the first plurality of comparison electrodes 602a, 602b and the second plurality of comparison electrodes 604a, 604b) are read separately at respective signal paths (e.g., sense (AS) electrodes deliver an out-of-plane acceleration signal via path 714 and comparison (ARS) electrodes deliver a comparison signal via path 712) in self-calibration mode. In some embodiments, signals received from sense (AS) electrodes and comparison (ARS) electrodes may be multiplexed (e.g., with respect to time, frequency, amplitude, wavelength, orthogonal codes, phase, etc.) and delivered over a single signal path to processing self-calibration mode 720. Processing self-calibration mode 720 receives the out-of-plane acceleration signal, generated by sense (AS) electrodes with respect to, e.g., proof mass 304 at processing input 726 and the comparison signal, generated by comparison (ARS) electrodes with respect to, e.g., proof mass 304. Processing circuitry performs operations such as those described in equation (2) below:

$${O}_{selfcal} = {G}_{AS} [ Δ {C}_{AS} ( a ) - α Δ {C}_{ARS} ( a ) ] \qquad ( 2 )$$

where:
O_{selfcal}=Out-of-plane accelerometer offset
a=output signal; see equation (1)
G_{AS}=Gain of sense (AS) electrode signal path in operation mode
ΔC_{AS}=Differential of capacitive engagement between sense (AS) electrodes and proof mass
α=Estimator gain
ΔC_{ARS}=Differential of capacitive engagement between comparison (ARS) electrodes and proof mass

Once processing circuitry (e.g., processing circuitry 104) determines O_{selfcal}, processing circuitry may compensate for the offset of the out-of-plane accelerometer, caused by deformation of, e.g., substrate layer 322, and enter processing operation mode 736 via processing input 744 such that RS<RS Threshold (e.g., the self_cal_enable code is set to zero at step 732). Processing circuitry subtracts O_{selfcal} from the output of the accelerometer to obtain the reading of the applied acceleration compensated for substrate deformations.

In some embodiments, out-of-plane acceleration may only cause tilt of, e.g., proof mass 304 within the MEMS layer, in which case the ratio between sense (AS) electrodes and comparison (ARS) electrodes does not change with acceleration, thus O_{selfcal} does not depend on applied acceleration.

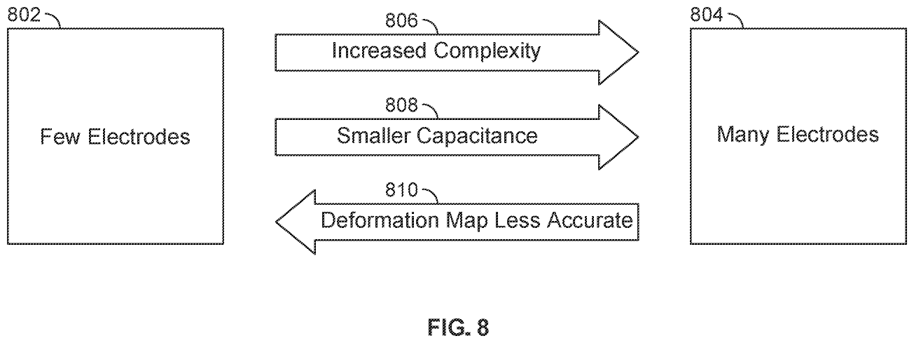

FIG. 8 shows an illustrative deformation mapping flowchart in accordance with an embodiment of the present disclosure. Although particular steps are depicted in certain configurations for FIG. 8, steps may be removed, modified, or substituted and additional steps may be added in certain embodiments. Step 802 highlights an embodiment where few electrodes (e.g., the first plurality of sense electrodes 308a, 308b, the second plurality of sense electrodes 310a, 310b, the first plurality of comparison electrodes 602a, 602b, and the second plurality of comparison electrodes 604a, 604b) are positioned on an upper surface of a substrate layer (e.g., substrate layer 322) below a MEMS layer (e.g., including proof mass 304) to map a deformation pattern of the substrate layer relative to the MEMS layer. Fewer electrodes 802 provides a more crude, less accurate mapping 810 of the deformation pattern of the substrate layer. It will be understood that the sense (AS) electrodes also contribute to sensitivity towards out-of-plane acceleration. In some embodiments, sense (AS) electrodes and comparison (ARS) electrodes may be further split to enhance accuracy of deformation mapping of the substrate layer. Increasing the number of AS and ARS electrodes to many electrodes 804 enhances characterization of the substrate layer deformation but also increases complexity 806 due to reading more capacitances separately. In some embodiments, a finer reconstruction of the deformation pattern may improve both offset and sensitivity correction. It will be understood that a combination of AS and ARS electrodes may be used to create an optimized estimator of out-of-plane acceleration. In some embodiments, using more electrodes forces a reduction in electrode size and capacitance 808, which may make each capacitance reading less accurate with many electrodes 804.

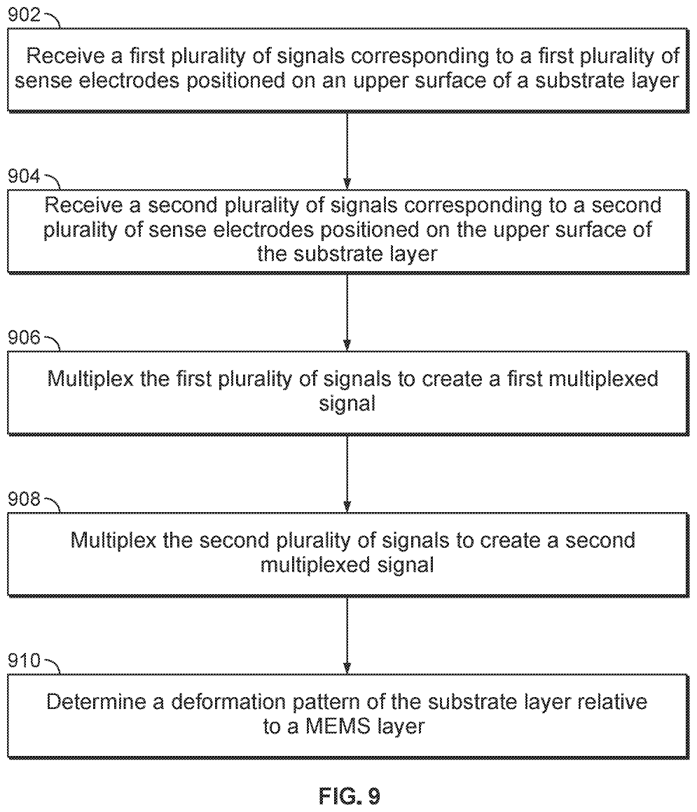

FIG. 9 shows an illustrative flowchart for out-of-plane sense electrode split sensing in accordance with an embodiment of the present disclosure. Although particular steps are depicted in certain configurations for FIG. 9, steps may be removed, modified, or substituted and additional steps may be added in certain embodiments.

At step 902, processing circuitry (e.g., processing circuitry 104) receives a first plurality of signals (e.g., the first plurality of signals 314a-314e) corresponding to a first plurality of sense electrodes (e.g., the first plurality of sense electrodes 308a-308e) positioned on an upper surface of a substrate layer (e.g., substrate layer 322). The first plurality of sense electrodes (e.g., the first plurality of sense electrodes 308a-308e) is of a first polarity (e.g., a positive charge) and is positioned on the upper surface, or plane, of the substrate layer (e.g., substrate layer 322) beneath a first portion of a proof mass (e.g., proof mass 304) within a MEMS layer. The proof mass (e.g., proof mass 304) is suspended in the MEMS layer, via torsional springs (e.g., torsional springs 312a, 312b), which enable the first portion of the proof mass (e.g., proof mass 304) to move out-of-plane with respect to the first plurality of sense electrodes (e.g., the first plurality of sense electrodes 308a-308e), forming a moving capacitor and generating the first plurality of signals (e.g., the first plurality of signals 314a-314e) in response to, e.g., a drive signal (e.g., drive signal 302), an out-of-plane acceleration, etc.

At step 904, processing circuitry (e.g., processing circuitry 104) receives a second plurality of signals (e.g., the second plurality of signals 316a-316e) corresponding to a second plurality of sense electrodes (e.g., the second plurality of sense electrodes 310a-310e) positioned on the upper surface of the substrate layer (e.g., substrate layer 322). The second plurality of sense electrodes (e.g., the second plurality of sense electrodes 310a-310e), split from the first plurality of sense electrodes (e.g., the first plurality of sense electrodes 308a-308e) and of a second polarity opposite the first polarity (e.g., a negative charge), is positioned on the upper surface, or plane, of the substrate layer (e.g., substrate layer 322) beneath a second portion of the proof mass (e.g., proof mass 304) within the MEMS layer. The proof mass (e.g., proof mass 304) is suspended in the MEMS layer, via torsional springs (e.g., torsional springs 312a, 312b), which enable the second portion of the proof mass (e.g., proof mass 304) to move out-of-plane with respect to the second plurality of sense electrodes (e.g., the second plurality of sense electrodes 310a-310e), forming a moving capacitor and generating the second plurality of signals (e.g., the second plurality of signals 316a-316e) in response to, e.g., a drive signal (e.g., drive signal 302), an out-of-plane acceleration, etc.

At step 906, processing circuitry (e.g., processing circuitry 104—including MUX 318a) multiplexes the first plurality of signals (e.g., the first plurality of signals 314a-314e) to create a first multiplexed signal (e.g., first multiplexed signal 324a), and, at step 908, processing circuitry (e.g., processing circuitry 104—including MUX 318b) multiplexes the second plurality of signals (e.g., the second plurality of signals 316a-316e) to create a second multiplexed signal (e.g., second multiplexed signal 324b). In some embodiments, processing circuitry (e.g., processing circuitry 104) may respectively multiplex the first plurality of signals (e.g., the first plurality of signals 314a-314e) and the second plurality of signals (e.g., the second plurality of signals 316a-316e) with respect to frequency, time, wavelength, phase, amplitude, or orthogonal codes.

At step 910, processing circuitry (e.g., processing circuitry 104—including C2V converter 320) determines a deformation pattern of the substrate layer (e.g., substrate layer 322) relative to the MEMS layer (e.g., including proof mass 304). A C2V converter (e.g., C2V converter 320) receives the first multiplexed signal (e.g., first multiplexed signal 324a) from a first MUX (e.g., MUX 318a), receives the second multiplexed signal (e.g., second multiplexed signal 324b) from a second MUX (e.g., MUX 318b), and provides the output signals to processing circuitry to determine the deformation pattern of the substrate layer (e.g., substrate layer 322) with respect to the MEMS layer (e.g., including proof mass 304) based on the first multiplexed signal (e.g., first multiplexed signal 324a) and the second multiplexed signal (e.g., second multiplexed signal 324b). The deformation pattern of the substrate layer (e.g., substrate layer 322) may be either of an asymmetric pattern or a symmetric pattern. It will be understood that the deformation pattern of the substrate layer (e.g., substrate layer 322) contributes to an offset and/or sensitivity of the out-of-plane accelerometer, so the determination of the deformation pattern by processing circuitry (e.g., processing circuitry 104) enables processing circuitry to improve offset and/or sensitivity stability of the out-of-plane accelerometer and more accurately estimate out-of-plane acceleration.

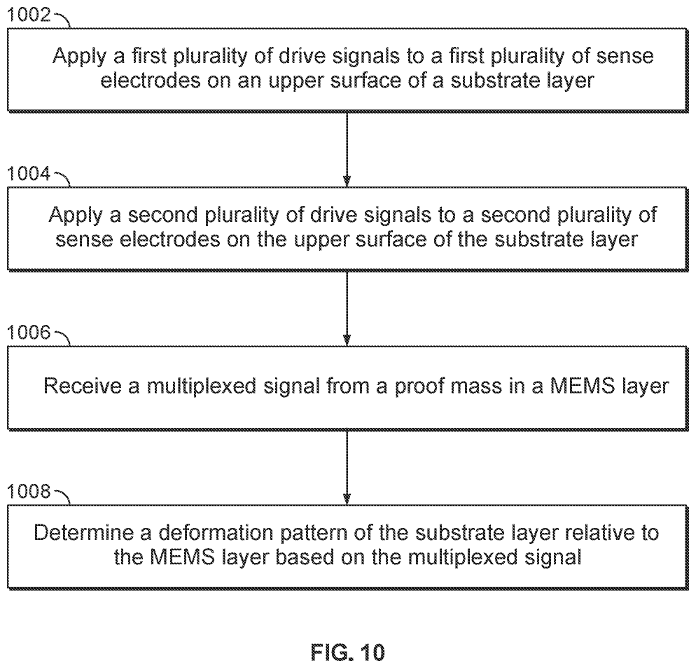

FIG. 10 shows an illustrative flowchart for proof mass sensing in accordance with an embodiment of the present disclosure. Although particular steps are depicted in certain configurations for FIG. 10, steps may be removed, modified, or substituted and additional steps may be added in certain embodiments.

At step 1002, processing circuitry applies a first plurality of drive signals (e.g., the first plurality of drive signals 402a-402e) to a first plurality of sense electrodes (e.g., the first plurality of sense electrodes 308a-308e), of a first polarity (e.g., a positive charge), on an upper surface of a substrate layer (e.g., substrate layer 322) beneath a MEMS layer (e.g., including proof mass 304). Each of the first plurality of drive signals (e.g., the first plurality of drive signals 402a-402e) actuates each of the first plurality of sense electrodes (e.g., the first plurality of sense electrodes 308a-308e) to capacitively engage with a first portion of a proof mass (e.g., proof mass 304) in the MEMS layer, which, based on a differential of the out-of-plane movement of the first portion of the proof mass (e.g., proof mass 304) with respect to the first plurality of sense electrodes (e.g., the first plurality of sense electrodes 308a-308e), generates a first plurality of capacitive signals that are delivered to the proof mass (e.g., proof mass 304), via a fixed portion (e.g., fixed portion 306) of the MEMS layer, and modulated and effectively multiplexed by the proof mass (e.g., proof mass 304).

At step 1004, processing circuitry (e.g., processing circuitry 104—a phase-locked loop (PLL)) applies a second plurality of drive signals (e.g., the second plurality of drive signals 404a-404e) to a second plurality of sense electrodes (e.g., the second plurality of sense electrodes 310a-310e), split from the first plurality of sense electrodes (e.g., the first plurality of sense electrodes 308a-308e) and of a second polarity opposite the first polarity (e.g., a negative charge), on the upper surface of the substrate layer (e.g., substrate layer 322) beneath the MEMS layer (e.g., including proof mass 304). Each of the second plurality of drive signals (e.g., the second plurality of drive signals 404a-404e) actuates each of the second plurality of sense electrodes (e.g., the second plurality of sense electrodes 310a-310e) to capacitively engage with a second portion of the proof mass (e.g., proof mass 304) in the MEMS layer, which, based on a differential of the out-of-plane movement of the second portion of the proof mass (e.g., proof mass 304) with respect to the second plurality of sense electrodes (e.g., the second plurality of sense electrodes 310a-310e), generates a second plurality of capacitive signals that are delivered to the proof mass (e.g., proof mass 304), via the fixed portion (e.g., fixed portion 306) of the MEMS layer, and modulated and effectively multiplexed by the proof mass (e.g., proof mass 306).

At step 1006, processing circuitry (e.g., processing circuitry 104—including C2V converter 410) receives a modulated and multiplexed signal (e.g., modulated and multiplexed signal 406) from the proof mass (e.g., proof mass 304) in the MEMS layer. At step 1008, processing circuitry (e.g., processing circuitry 104—including C2V converter 410 and demodulator 412) determines a deformation pattern of the substrate layer (e.g., substrate layer 322) relative to the MEMS layer (e.g., including proof mass 304) based on the multiplexed signal (e.g., multiplexed signal 406). A C2V converter (e.g., C2V converter 410) determines the deformation pattern (e.g., an asymmetric or symmetric pattern) of the substrate layer (e.g., substrate layer 322) with respect to the MEMS layer (e.g., including proof mass 304) based on the output signal by mapping sense gaps in different locations of the proof mass (e.g., proof mass 304). Processing circuitry (e.g., processing circuitry 104) determining the deformation pattern of the substrate layer (e.g., substrate layer 322) relative to the MEMS layer (e.g., including proof mass 304) enables the MEMS accelerometer to improve offset and/or sensitivity stability of the out-of-plane accelerometer and more accurately estimate out-of-plane acceleration.

The foregoing description includes exemplary embodiments in accordance with the present disclosure. These examples are provided for purposes of illustration only and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical system (MEMS) sensor, comprising:
a MEMS layer including a fixed portion and a proof mass, wherein the proof mass moves in response to an external excitation;
a substrate layer, located beneath the MEMS layer, including a first plurality of sense electrodes associated with a first portion of the proof mass and a second plurality of sense electrodes associated with a second portion of the proof mass, wherein the first portion of the proof mass and the second portion of the proof mass each move normal to the MEMS layer, the first portion in a first direction and the second portion in a second direction opposite the first direction; and
processing circuitry configured to determine a deformation pattern of the substrate layer relative to the MEMS layer based on a comparison of signals received from the first plurality of sense electrodes and the second plurality of sense electrodes.

2. The MEMS sensor of claim 1, further comprising tilt sense electrodes located on an upper surface of the substrate layer, wherein the tilt sense electrodes are associated with the fixed portion of the MEMS layer.

3. The MEMS sensor of claim 2, wherein, in response to receiving a measurement based on a distance between the tilt sense electrodes and the fixed portion of the MEMS layer, the processing circuitry compares the measurement to a threshold.

4. The MEMS sensor of claim 3, wherein the processing circuitry determines the deformation pattern based on the measurement exceeding the threshold.

5. The MEMS sensor of claim 2, further comprising a first plurality of comparison electrodes and a second plurality of comparison electrodes, wherein the first plurality of comparison electrodes is located between the tilt sense electrodes and the first plurality of sense electrodes, and wherein the second plurality of comparison electrodes is located between the tilt sense electrodes and the second plurality of sense electrodes.

6. The MEMS sensor of claim 5, wherein the processing circuitry determines the deformation pattern based on a comparison of each of the signals received from the first plurality of sense electrodes, the first plurality of comparison electrodes, the second plurality of sense electrodes, and the second plurality of comparison electrodes.

7. The MEMS sensor of claim 5, wherein each of the comparison electrodes define a smaller surface area than the sense electrodes.

8. The MEMS sensor of claim 1, wherein the external excitation is acceleration, Coriolis, magnetic, barometric pressure, or sound pressure.

9. The MEMS sensor of claim 1, wherein the processing circuitry measures the external excitation based on the signals received from the first plurality of sense electrodes and second plurality of sense electrodes, the processing circuitry further determines an offset of the measured external excitation based on the deformation pattern.

10. The MEMS sensor of claim 9, wherein the processing circuitry modifies the measured external excitation based on the offset.

11. The MEMS sensor of claim 9, wherein the processing circuitry determines a sensitivity of the measured external excitation based on the deformation pattern.

12. The MEMS sensor of claim 11, wherein the processing circuitry modifies the measured external excitation based on the sensitivity.

13. The MEMS sensor of claim 1, wherein the processing circuitry receives each of the signals from the first plurality of sense electrodes and each of the signals from the second plurality of sense electrodes separately, and maps sense gaps in different locations of the proof mass based on the signals received from the first plurality of sense electrodes and the second plurality of sense electrodes.

14. The MEMS sensor of claim 1, wherein the processing circuitry is configured to multiplex each of the signals received from the first plurality of sense electrodes and the second plurality of sense electrodes into a first multiplexed signal, corresponding to the first plurality of sense electrodes, and a second multiplexed signal, corresponding to the second plurality of sense electrodes, and wherein the deformation pattern is determined based on respective comparisons of portions of the first multiplexed signal and portions of the second multiplexed signal.

15. The MEMS sensor of claim 1, wherein, in response to drive signals applied to each of the first plurality of sense electrodes and each of the second plurality of sense electrodes, the processing circuitry receives a multiplexed signal from the proof mass and determines the deformation pattern based on the multiplexed signal, and wherein the of signals received from the first plurality of sense electrodes and the second plurality of sense electrodes are received via the multiplexed signal of the proof mass.

16. The MEMS sensor of claim 15, wherein a multiplexing of the multiplexed signal is based on one of time, amplitude, phase, frequency, or orthogonal codes.

17. The MEMS sensor of claim 1, wherein the first plurality of sense electrodes has a first polarity, and the second plurality of sense electrodes has a second polarity, the second polarity being opposite the first polarity.

18. A method, comprising:
receiving a first plurality of signals corresponding to a first plurality of sense electrodes positioned on an upper surface of a substrate layer, wherein each of the first plurality of signals is based on a first distance between a first portion of a proof mass and the first plurality of sense electrodes;
receiving a second plurality of signals corresponding to a second plurality of sense electrodes positioned on the upper surface of the substrate layer, wherein each of the second plurality of signals is based on a second distance of a second portion of the proof mass from the second plurality of sense electrodes;
multiplexing the first plurality of signals to create a first multiplexed signal;
multiplexing the second plurality of signals to create a second multiplexed signal; and
determining a deformation pattern of the substrate layer relative to a MEMS layer based on the first multiplexed signal and the second multiplexed signal.

19. A method, comprising:
applying a first plurality of drive signals to a first plurality of sense electrodes positioned on an upper surface of a substrate layer, wherein each of the first plurality of sense electrodes generates a respective first signal based on a distance to a first portion of a proof mass in a MEMS layer to form a plurality of first signals;
applying a second plurality of drive signals to a second plurality of sense electrodes positioned on the upper surface of the substrate layer, wherein each of the second plurality of sense electrodes generates a respective second signal based on a distance to a second portion of the proof mass in the MEMS layer to form a plurality of second signals;
receiving a multiplexed signal from the proof mass, wherein the multiplexed signal includes the plurality of first signals and the plurality of second signals; and
determining a deformation pattern of the substrate layer relative to the MEMS layer based on the multiplexed signal.
